(19) United States
(12) Patent Application Publication
(10) Pub. No.: US 2015/0372235 A1
(43) Pub. Date: Dec. 24, 2015

(54) ORGANIC THIN FILM TRANSISTOR USING LOCAL ETCHING AND MANUFACTURING METHOD THEREOF

(71) Applicant: YONG-YOUNG NOH, DAEJEON (KR)

(72) Inventor: YONG-YOUNG NOH, DAEJEON (KR)

(21) Appl. No.: 14/444,671

(22) Filed: Jul. 28, 2014

(30) Foreign Application Priority Data
Jun. 24, 2014 (KR) 10-2014-0077485

(51) Int. Cl. H01L 51/00; H01L 51/05; H01L 51/10

(52) U.S. Cl. CPC H01L 51/0019; H01L 51/105; H01L 51/0541; H01L 51/0072; H01L 51/0068

(57) ABSTRACT

Disclosed herein is a method of manufacturing an organic thin film transistor, including the steps of: forming a first insulation layer on a semiconductor layer; locally etching the first insulation layer; and forming a second insulation layer on the first insulation layer including the etched region thereof, wherein the etching of the first insulation layer is conducted by inkjet printing.

### BACKGROUND OF THE INVENTION

1. Technical Field

The present invention relates to a method of manufacturing an organic thin film transistor using an etching process, wherein the etching process is carried out by printing.

2. Description of the Related Art

Recently, flexible displays have attracted considerable attention. Since users need a portable large-screen display, it is required to develop a foldable, bendable or rollable display. Further, if a solution-based process or a roll to roll process becomes possible, such a flexible display can be produced at lower cost. For this purpose, it is required to use a bendable substrate such as a stainless steel substrate and to reduce a process temperature to 300° C. or lower. As a transistor for a driving circuit, which can be manufactured at such a low temperature, research into an organic thin film transistor (OTFT) has recently been actively conducted.

Meanwhile, an active matrix (AM) drive system is necessary for high resolution and low power driving. However, a currently-used inorganic thin film transistor, such as a silicon thin film transistor, has a limitation in being applied to flexible and stretchable displays because its manufacturing temperature is high and it easily breaks when it is bent or stretched, and has another limitation in that it cannot be mixed with a different material and then used in a solution-based process, as it is non-soluble after mixing. Therefore, research into an organic thin film transistor, which can be easily manufactured by a solution-based process and which cannot be damaged even when it is warped or bent, has actively been conducted.

Such an organic thin film transistor has actively been researched as a drive element of a next-generation display, and is expected to be used in the fabrication of a radio-frequency identification (RFID) tag that can be applied to the recognition of an individual article. An organic thin film transistor uses an organic semiconductor film instead of a silicon film as a semiconductor layer. Organic thin film transistors are classified into low-molecular weight organic thin film transistors, such as oligothiophene and pentacene, and high-molecular weight organic thin film transistors, such as polythiophene-based polymers according to the raw material of the organic semiconductor film.

However, in order to manufacture an organic thin film transistor and an electronic circuit using the same, an etching process is required. Since a general etching process is carried out through several steps, impurities are generated with respect to each step, and thus a procedure of removing the impurities is required.

Accordingly, a general organic thin film transistor is problematic in that it is difficult to be manufactured by means of a continuous process.

Therefore, it is required to develop an organic thin film transistor which can be manufactured by a continuous process and the characteristics of which can be improved even when a two or more layer-laminated insulation film is used.

### SUMMARY OF THE INVENTION

Accordingly, the present invention has been devised to solve the above-mentioned problems, and an object of the present invention is to provide a process of manufacturing an organic thin film transistor, by which an organic thin film transistor and an electronic circuit based on the same can be manufactured by a simple process and the performance thereof can be improved.

Another object of the present invention is to provide an organic thin film transistor, the performance of which can be improved by using various semiconductor layers, compared to conventional organic thin film transistors.

In order to accomplish the above objects, an aspect of the present invention provides a method of manufacturing an organic thin film transistor, including the steps of: forming a first insulation layer on a semiconductor layer; locally etching the first insulation layer; and forming a second insulation layer on the first insulation layer including the etched region thereof, wherein the etching of the first insulation layer is conducted by inkjet printing.

Another aspect of the present invention provides a method of manufacturing an organic thin film transistor, including the steps of: providing a substrate; forming source/drain electrodes on the substrate; forming an organic semiconductor layer on the source/drain electrodes; forming a first insulation layer on the organic semiconductor layer; locally etching a part of the first insulation layer; forming a second insulation layer on the first insulation layer including the etched region thereof; and forming a gate electrode on the second insulation layer, wherein the first insulation layer is etched using an etching solvent by inkjet printing.

In the method, the organic semiconductor layer may include both an N-type semiconductor layer and a P-type semiconductor layer, and the first insulation layer may be different from the second insulation layer.

Further, after the step of etching the first insulation layer, the first insulation layer or second insulation layer may be applied onto the N-type semiconductor layer, and the first insulation layer or second insulation layer being in contact with the N-type semiconductor layer may be made of any one of polystyrene (PS), a fluoropolymer (CYTOP), and poly(methylmethacrylate) (PMMA).

Further, after the step of etching the first insulation layer, the first insulation layer or second insulation layer may be applied onto the P-type semiconductor layer, and the first insulation layer or second insulation layer being in contact with the P-type semiconductor layer may be made of any one of P(VDF-TrFE) (poly(vinylidene fluoride-trifluoroethylene)), (P(VDF-TrFE-CFE)) (poly(vinylidene fluoride-trifluoroethylene-1, 1-chlorofluoroethylene)), and P(VDF-TrFE-CTFE) (poly(vinylidene fluoride-trifluoroethylene-chlorotrifluoro ethylene)).

Further, in the step of etching the first insulation layer, a part of the first insulation layer may be locally etched using an etching solvent by inkjet printing, and the etching solvent may be any one of n-butyl acetate (n-BA), 2-ethoxyethanol (2-E), 3-methoxypropiontrile (3-M), propylene glycol methyl ether acetate (PGMEA), 1,2-dichloroethane (1,2-DCF), and 1-butanol (1-BuOH).

Further, the organic semiconductor may be an amphoteric organic semiconductor, an N-type organic semiconductor or a P-type organic semiconductor. Here, the amphoteric organic semiconductor may be any one selected from among: P(NDI2OD-T2)(Naphthalene-bis(dicarboximide) bithiophene), F8BT, PFO, DPPT-TT(diketopyrrolo-pyrrole-bithiophene), and PTVPhI-Eh; the N-type organic semiconductor may be any one selected from among: an acene material, a completely-fluorinated acene material, a partially-fluorinated acene material, a partially-fluorinated oligothiophene material, a fullerene material, a substituent-containing fullerene material, a completely-fluorinated phthalocyanine material, a partially-fluorinated phthalocyanine material, a perylene tetracarboxylic diimide material, a perylene tetracarboxylic dianhydride material, a naphthalene tetracarboxylic diimide material, and a naphthalene tetracarboxylic dianhydride material; and the P-type organic semiconductor may be any one selected from among: acene, poly-thienylenevinylene, poly-3-hexylthiophene, α-hexathienylene, naphthalene, α-6-thiophene, α-4-thiophene, rubrene, polythiophene, polyparaphenylenevinylene, polyparaphenylene, polythiophenevinylene, a polythiophene-heterocyclicaromatic copolymer, and triarylamine.

Still another aspect of the present invention provides an organic thin film transistor, including: a substrate; source/drain electrodes disposed on the substrate and spaced apart from each other; an organic semiconductor layer formed on the source/drain electrodes and including an N-type semiconductor layer and a P-type semiconductor layer; a first insulation layer disposed on the entire surface of the organic semiconductor layer; a second insulation layer disposed on the entire surface of the first insulation layer; and a gate electrode disposed on the second insulation layer, wherein the first insulation layer is etched on the N-type semiconductor layer or the P-type semiconductor layer by inkjet printing.

In the transistor, the first insulation layer may be different from the second insulation layer.

Further, the first insulation layer or second insulation layer may be applied onto the N-type semiconductor layer, and the first insulation layer or second insulation layer being in contact with the N-type semiconductor layer may be made of any one of polystyrene (PS), a fluoropolymer (CYTOP) and poly(methylmethacrylate) (PMMA).

Further, the first insulation layer or second insulation layer may be applied onto the P-type semiconductor layer, and the first insulation layer or second insulation layer being in contact with the P-type semiconductor layer may be made of any one of P(VDF-TrFE) (poly(vinylidene fluoride-trifluoroethylene)), (P(VDF-TrFE-CFE)) (poly(vinylidene fluoride-trifluoroethylene-1, 1-chlorofluoroethylene)), and P(VDF-TrFE-CTFE) (poly(vinylidene fluoride-trifluoroethylene-chlorotrifluoro ethylene)).

Further, a part of the first insulation layer may be locally etched using an etching solvent by inkjet printing, and the etching solvent may be any one of n-butyl acetate (n-BA), 2-ethoxyethanol (2-E), 3-methoxypropiontrile (3-M), propylene glycol methyl ether acetate (PGMEA), 1,2-dichloroethane (1,2-DCE), and 1-butanol (1-BuOH).

As described above, the organic thin film transistor according to the present invention is advantageous in that, when solvent etching is carried out by inkjet printing, the solvent itself melts an insulation layer to etch the insulation layer, so it is not required to remove impurities, thereby manufacturing this transistor by means of a continuous process.

Further, the organic thin film transistor according to the present invention is advantageous in that its manufacturing process can be easily controlled by a computer program because a continuous process can be carried out.

Further, the organic thin film transistor according to the present invention is economically advantageous in that its manufacturing cost can be reduced because its manufacturing process is simple.

Further, the organic thin film transistor according to the present invention is advantageous in that it is used in a CMOS inverter device including both N-type semiconductors and P-type semiconductors to improve the performance of the device.

### BRIEF DESCRIPTION OF THE DRAWINGS

The above and other objects, features and advantages of the present invention will be more clearly understood from the following detailed description taken in conjunction with the accompanying drawings, in which:

Each of FIGS. 1 and 2 schematically shows a process of manufacturing an organic thin film transistor according to an embodiment of the present invention;

FIG. 3 shows the state of an organic semiconductor layer which was not etched by n-butyl acetate as a solvent;

FIG. 4 is an optical micrograph of the etched region of a first insulation layer according to an embodiment of the present invention;

FIG. 5 is an atomic force micrograph of the etched region of a first insulation layer according to an embodiment of the present invention;

FIG. 6 presents graphs showing the respective performance of two semiconductor layers of the organic thin film transistor of Example 1;

FIG. 7 presents graphs comparing the respective performance of the organic thin film transistors of Example 1, Comparative Example 1 and Comparative Example 2; and

FIG. 8 presents a photograph (a) of a ring oscillator manufactured using the organic thin film transistor of Example 1 and a graph (b) showing the characteristics of the ring oscillator, wherein Fosc characteristics of the organic thin film transistors of Example 1 and Comparative Example 1 are shown.

### DESCRIPTION OF THE PREFERRED EMBODIMENTS

Hereinafter, preferred embodiments of the present invention will be described in detail with reference to the attached drawings. Throughout the accompanying drawings, the same reference numerals are used to designate the same or similar components, and redundant descriptions thereof are omitted. Further, in the description of the present invention, when it is determined that the detailed description of the related art would obscure the gist of the present invention, the description thereof will be omitted.

The terms “approximately”, “substantially” and the like used herein are used as the meaning that the numerical value corresponds to or approximate to the presented allowable error. Unless otherwise defined, all terms including technical and scientific terms used herein have the same meaning as commonly understood by one of ordinary skill in the art to which this invention belongs.

Each of FIGS. 1 and 2 schematically shows a process of manufacturing an organic thin film transistor according to an embodiment of the present invention.

A top gate-type organic thin film transistor is manufactured by a process including the steps of: providing a substrate; forming source/drain electrodes on the substrate such that these source/drain electrodes are spaced apart from each other; forming an organic semiconductor layer to cover the source/drain electrodes; forming an insulation layer on the organic semiconductor layer; and forming a gate electrode on a partial region of the insulation layer.

The organic thin film transistor of the present invention can be used in a CMOS inverter device including both an N-type semiconductor and a P-type semiconductor.

Referring to FIG. 1, a substrate is provided, and source/drain electrode spaced apart from each other are formed on the substrate.

As the substrate, a transparent substrate such as a glass substrate or a flexible substrate such as a silicon substrate, a plastic substrate or a metal foil substrate may be used. The plastic substrate may be made of polyethersulphone, polyacrylate, polyetherimide, polyethylene napthalate, polyethyelene terepthalate, polyphenylene sulfide, polyallylate, polyimide, polycarbonate, cellulose triacetate, cellulose acetate propinoate or the like.

Each of the source/drain electrodes may be formed of a monolayer made of any one selected from among Au, Al, Ag, Mg, Ca, Yb, Cs-ITO and alloys thereof, and may be formed of a multi-layer further including an adhesive metal layer made of Ti, Cr or Ni in order to improve the adhesivity thereof to the substrate. Meanwhile, graphene, carbon nanotubes (CNTs), conductive polymer (PEDOT-PSS) silver nanowires and the like may be used to manufacture a flexible element having higher elasticity than that of metal, and may be used to manufacture source/drain electrodes by using these materials as ink through inkjet printing or spray printing. Through such a printing process, source/drain electrodes can be formed, and vacuum processing can be excluded, thus reducing the manufacturing cost thereof.

An organic semiconductor layer is formed on the source/drain electrodes. The organic semiconductor layer may be formed of any one of an amphoteric organic semiconductor, an N-type organic semiconductor and a P-type organic semiconductor.

The amphoteric organic semiconductor may be any one selected from among P(NDI2OD-T2) (naphthalene-bis(dicarboximide) bithiophene), F8BT, PFO, DPPT-TT (diketopyrrolo-pyrrole-bithiophene), and PTVPhI-Eh.

The N-type organic semiconductor may be any one selected from among an acene material, a completely-fluorinated acene material, a partially-fluorinated acene material, a partially-fluorinated oligothiophene material, a fullerene material, a substituent-containing fullerene material, a completely-fluorinated phthalocyanine material, a partially-fluorinated phthalocyanine material, a perylene tetracarboxylic diimide material, a perylene tetracarboxylic dianhydride material, a naphthalene tetracarboxylic diimide material, and a naphthalene tetracarboxylic dianhydride material. Here, the acene material may be selected from among anthracene, tetracene, pentacene, perylene, and coronene.

Further, the P-type organic semiconductor may be any one selected from among acene, poly-thienylenevinylene, poly-3-hexylthiophene, α-hexathienylene, naphthalene, α-6-thiophene, α-4-thiophene, rubrene, polythiophene, polyparaphenylenevinylene, polyparaphenylene, polythiophenevinylene, a polythiophene-heterocyclicaromatic copolymer, triarylamine, and derivatives thereof. Here, the acene may be selected from among pentacene, perylene, tetracene, and anthracene.

The organic semiconductor layer is formed on the source/drain electrodes by spin coating, spray coating, inkjet printing, flexography, screen printing, dip coating, gravure coating or the like. Thus, patterns can be formed on the source/drain electrode and on the local region of the substrate, and heat treatment or optical exposure may be carried out in order to improve the element performance, such as semiconductor crystallinity and stability, after the formation of the organic semiconductor layer.

A first insulation layer may be formed on the entire surface of the organic semiconductor layer (step of foisting a first insulation layer).

The first insulation layer may be made of an organic polymer because it must be completely melted by an etchant. For example, the organic polymer may be any one selected from the group consisting of polystyrene (PS), polymethylmethacrylate (PMMA), phenolic polymers, acrylic polymers, imide polymers such as polyimide, arylether polymers, amide polymers, fluorine polymers, p-xylene polymers, vinylalcohol polymers, and parylene.

The first insulation layer may be classified as an insulation layer exhibiting excellent element performance when it makes contact with an N-type semiconductor layer or an insulation layer exhibiting excellent element performance when it makes contact with a P-type semiconductor layer. That is, the type of the insulation layer may be determined according to the type of semiconductor to be etched during an etching process.

In the case where the first insulation layer is to make contact with an N-type semiconductor layer, an insulation layer exhibiting excellent element performance when it makes contact with an N-type semiconductor layer may be used, and in the case where the first insulation layer is to make contact with a P-type semiconductor layer, an insulation layer exhibiting excellent element performance when it makes contact with a P-type semiconductor layer may be used.

When the first insulation layer made of polystyrene (PS), fluoropolymer (CYTOP) or polymethylmethacrylate (PMMA) is disposed to make contact with an N-type semiconductor layer, electron mobility increases, thus improving the element performance.

Further, when the first insulation layer made of P(VDF-TrFE) (Poly(vinylidene fluoride-trifluoroethylene)), (P(VDF-TrFE-CFE)) (Poly(vinylidene fluoride-trifluoroethylene-1, 1-chlorofluoroethylene)) or P(VDF-TrFE-CTFE) (Poly(vinylidene fluoride-trifluoroethylene-chlorotrifluoro ethylene)) is disposed to make contact with a P-type semiconductor layer, electron mobility increases, thus improving the element performance.

In FIG. 2, an etched region is formed on a P-type semiconductor layer to allow the first insulation layer to make contact with an N-type semiconductor layer. Here, this first insulation layer is made of polystyrene (PS).

Next, a part of the first insulation layer formed on the organic semiconductor layer may be locally etched (step of etching the first insulation layer).

In this case, in order to locally etch a part of the first insulation layer, inkjet printing is used.

Various technologies for forming an element such as an electrode, an organic semiconductor layer or the like using inkjet printing are generally used. However, in the present invention, an etching process for removing unnecessary portions can be carried out by inkjet printing using ink as a solvent.

In the case where an etching process is performed by inkjet printing, only a local region can be etched by a solvent, and thus etching can be locally carried out to a technically possible region using inkjet printing. That is, etching can be carried out to cover a region as small as 1 μm. Preferably, etching can be carried out to have an average diameter of 1 μm to 10 mm. In order to etch an organic semiconductor layer, it is technically difficult to use another printing process, and such an etching process can be carried out using only inkjet printing.

When an etching process is performed by inkjet printing, a transistor can be manufactured by continuous processes. In the case of a general etching process, this etching process includes 3˜4 steps, and a washing process for removing impurities is required after the etching process.

However, in the present invention, when an etching process is carried out using a solvent by inkjet printing, the solvent itself melts an insulation layer to perform the etching process, and thus it is not necessary to remove impurities, thereby allowing a transistor to be manufactured by a continuous process.

Further, the etching process is characterized in that any one of two types of organic semiconductor layers may be etched. For example, any one of an N-type organic semiconductor layer and a P-type organic semiconductor layer may be etched.

As the solvent necessary for the etching process, a solvent, which does not change an organic semiconductor layer while etching an insulation layer, must be used.

Examples of the solvent may include n-butyl acetate (n-BA), 2-ethoxyethanol (2-E), 3-methoxypropiontrile (3-M), propylene glycol methyl ether acetate (PGMEA), dichloroethane (DCE), and butanol (1-BuOH).

When the etching process is carried out by this solvent, the organic semiconductor layer is not influenced, and only the insulation layer is etched.

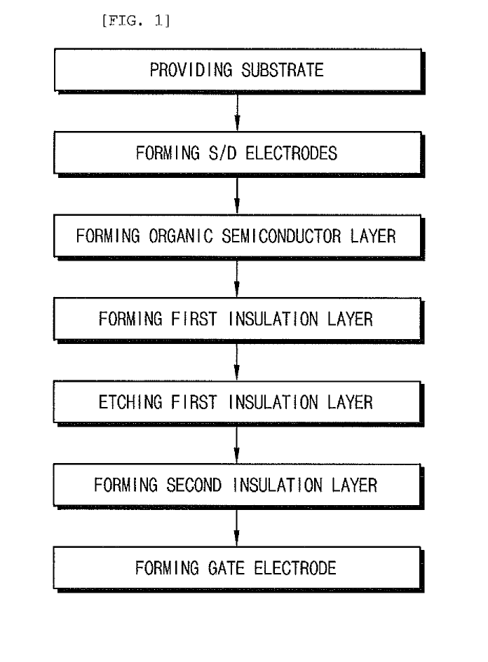

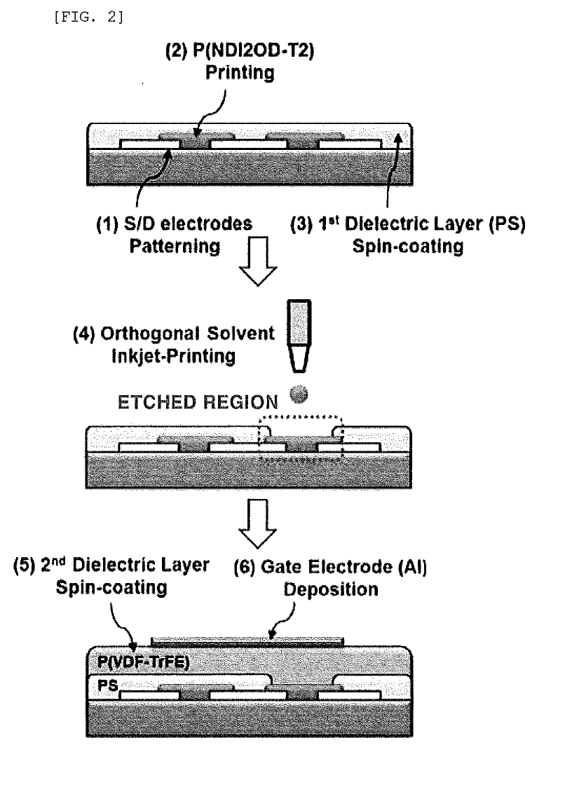

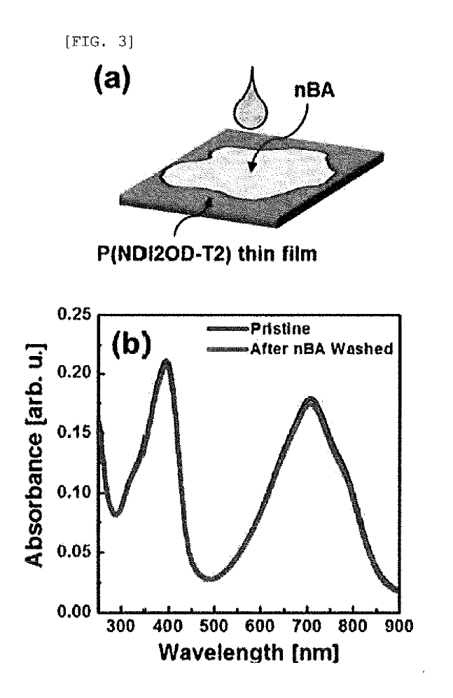

FIG. 3 shows the state of the organic semiconductor layer which was not etched by n-butyl acetate as the solvent.

The solvent n-butyl acetate serves to melt a polymer such as PS. In the present invention, a polymer such as PS is formed into an insulation layer, and then a part of the insulation layer is locally etched. Thus, an organic semiconductor layer is formed beneath the etched insulation layer. In this case, if the organic semiconductor layer is also etched by the solvent, the performance thereof will be remarkably deteriorated.

Referring to FIG. 3, (a) of FIG. 3 shows the state of a P(NDI2OD-T2) thin film, serving as an organic semiconductor layer, on which n-butyl acetate, serving as a solvent capable of etching an insulation layer, is applied. (b) of FIG. 3 is a graph showing the results of observing the P(NDI2OD-T2) thin film laid thereon with the n-butyl acetate.

Referring to (b) of FIG. 3, Comparing the UV absorbance (blue line) of the P(NDI2OD-T2) thin film, on which the solvent is not applied, with that (red line) thereof, on which the solvent is applied, it can be ascertained that there is no significant difference therebetween. Therefore, it can be ascertained that the solvent, n-butyl acetate, does not exert an influence on P(NDI2OD-T2) used as a semiconductor material at all.

That is, it can be ascertained that the organic semiconductor layer is not influenced at all, even when an etching process is performed after the organic semiconductor layer and the first insulation layer are laminated.

After the etching of the first insulation layer, a second insulation layer is formed on the first insulation layer including the etched region thereof (step of forming the second insulation layer).

The second insulation layer is different from the first insulation layer in type, and the type of the second insulation layer may be determined depending on the characteristics of the organic semiconductor layer of the etched insulation layer. That is, when the organic semiconductor layer is a P-type organic semiconductor layer, the second insulation layer can exhibit excellent performance when it is laminated on the P-type organic semiconductor layer; and when the organic semiconductor layer is an N-type organic semiconductor layer, the second insulation layer may be further laminated on the N-type organic semiconductor layer.

Further, when the organic semiconductor layer is an N-type organic semiconductor layer, the second insulation layer can exhibit excellent performance when it is laminated on the N-type organic semiconductor layer; and when the organic semiconductor layer is a P-type organic semiconductor layer, the second insulation layer may be further laminated on the p-type organic semiconductor layer.

The second insulation layer being in contact with the N-type semiconductor layer after etching may be made of polystyrene (PS), a fluoropolymer (CYTOP) or poly(methylmethacrylate) (PMMA). The second insulation layer being in contact with the P-type semiconductor layer after etching may be made of P(VDF-TrFE) (poly(vinylidene fluoride-trifluoroethylene)), (P(VDF-TrFE-CFE)) (poly(vinylidene fluoride-trifluoroethylene-1, 1-chlorofluoroethylene)) or P(VDF-TrFE-CTFE) (poly(vinylidene fluoride-trifluoroethylene-chlorotrifluoro ethylene)).

A gate electrode is formed on a part of the second insulation layer (step of forming the gate electrode).

The gate electrode may be made of any one selected from among aluminum (Al), an aluminum alloy (Al-alloy), molybdenum (Mo), a molybdenum alloy (Mo-alloy), silver nanowire, gallium indium eutectic, and PEDOT-PSS. The gate electrode may be formed by using such a material as ink through inkjet printing, spray printing or the like. Through such a printing process, the gate electrode can be formed, and vacuum processing can be excluded, thus reducing the manufacturing cost thereof.

In this way, an organic thin film transistor including an N-type organic semiconductor layer, a P-type organic semiconductor layer, a first insulation layer and a second insulation layer can be obtained.

Hereinafter, the present invention will be described in more detail with reference to the following Examples. However, these Examples are set forth to illustrate the present invention, and the scope of the present invention is not limited thereto.

### Example 1

### Provision of Substrate and Formation of Electrodes

In the manufacturing of an organic thin film transistor, a substrate is provided, and source/drain electrodes were formed on the substrate.

As shown in FIG. 2, in the formation of the source/drain electrodes, a drain electrode was formed at the center of the substrate, and source electrodes were formed at both sides of the drain electrode.

That is, a CMOS inverter device serving to form an N-type semiconductor layer and a P-type semiconductor layer was fabricated.

Formation of Organic Semiconductor Layer

An organic semiconductor layer was formed using the amphoteric organic semiconductor P(NDI2OD-T2). In the formation of the organic semiconductor layer, two organic semiconductor layers were formed such that the source (S) electrodes and the drain (D) electrode make contact with each other (refer to FIG. 2).

Formation of First Insulation Layer

A first insulation layer was formed on the substrate provided thereon with the organic semiconductor layer. The first insulation layer was formed by dissolving polystyrene (PS) in n-butyl acetate and then spin-coating the resulting solution.

Etching Process

After the formation of the first insulation layer, one of the two organic semiconductor layers was etched using n-butyl acetate as an etching solvent. The first insulation layer made of polystyrene (PS) was also etched using the etching solvent n-butyl acetate

Since the first insulation layer was formed by dissolving polystyrene (PS) in n-butyl acetate, when n-butyl acetate makes contact with the first insulation layer, polystyrene (PS) is melted, and thus the insulation layer is etched.

The etching of the first insulation layer was carried out by inkjet printing. Specifically, the etching thereof was carried out by inkjet printing using n-butyl acetate as ink.

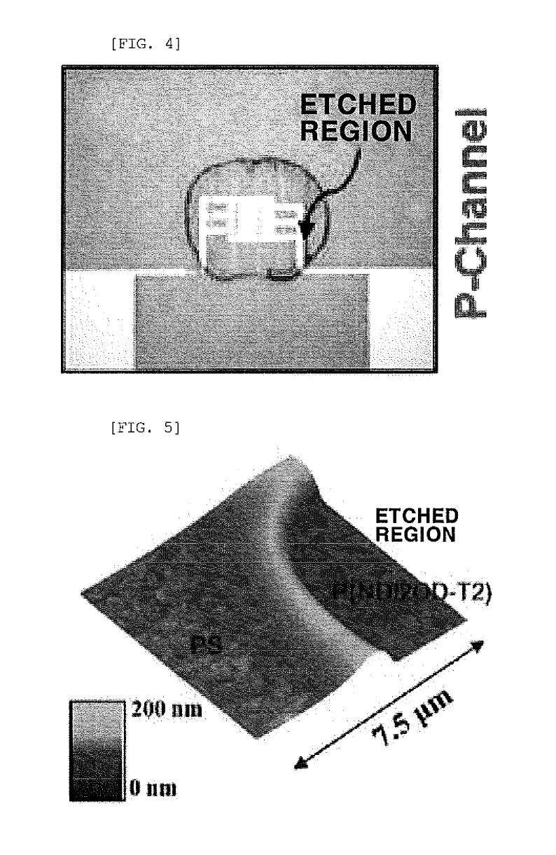

FIG. 4 is an optical micrograph of the etched region of the first insulation layer according to an embodiment of the present invention. Further, FIG. 5 is an atomic force micrograph of the etched region of the first insulation layer according to an embodiment of the present invention.

Referring to FIGS. 4 and 5, it can be ascertained that the etched region of the first insulation layer has a circular form, and the first insulation layer is removed in the form of a circle because it is etched using a solvent via inkjet printing.

Formation of Second Insulation Layer

A second insulation layer was formed on the initial insulation layer including the etched region thereof. P(VDF-TrFE) was used as the raw material of the second insulation layer, and the second insulation layer was formed on the entire surface of the first insulation layer including the etched region thereof. The second insulation layer was formed by spin coating.

Formation of Gate Electrode

A gate electrode was formed on a part of the second insulation layer by the deposition of aluminum (Al).

### Comparative Example 1

An organic thin film transistor was manufactured in the same manner as in Example 1, except that an etching process was not carried out, and only the second insulation layer made of P(VDF-TrFE) was used without the first insulation layer made of polystyrene (PS).

### Comparative Example 2

An organic thin film transistor was manufactured in the same manner as in Example 1, except that an etching process was not carried out, and the first insulation layer made of PS and the second insulation layer made of P(VDF-TrFE) were formed on the organic semiconductor layer.

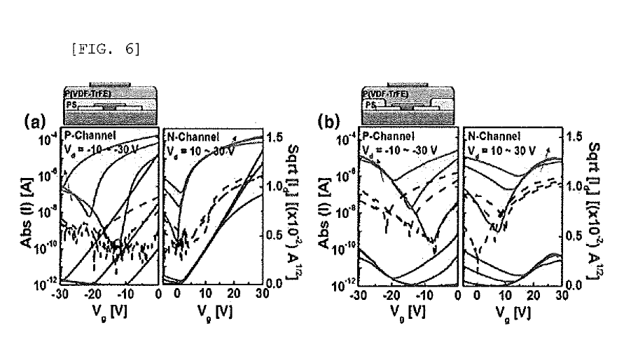

FIG. 6 shows the respective performance of two semiconductor layers of the organic thin film transistor of Example 1.

As shown in (a) of FIG. 6, the interface between the polystyrene (PS) insulation layer and the organic semiconductor layer is suitable for the movement of electrons due to the increase in accumulation of electrons, and, as shown in (b) of FIG. 6, the interface between the P(VDF-TrFE) insulation layer and the organic semiconductor layer is suitable for the movement of holes due to the increase in accumulation of holes. Therefore, when both the polystyrene (PS) insulation layer and the P(VDF-TrFE) insulation layer are used, high current and mobility can be obtained from an N-type semiconductor transistor, and, conversely, when only the P(VDF-TrFE) insulation layer is used by etching, high current and mobility can be obtained from a P-type semiconductor transistor

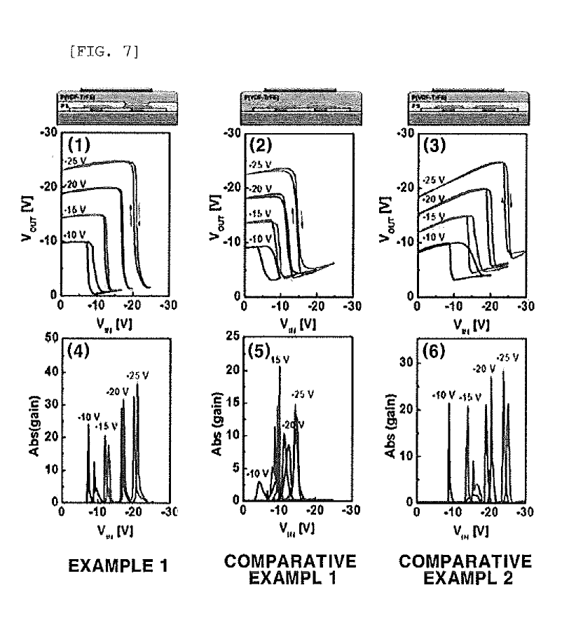

FIG. 7 compares the respective performance of the inverters (organic thin film transistors) of Example 1, Comparative Example 1 and Comparative Example 2.

In order for each of the inverters to exhibit excellent characteristics, voltage loss must be low. Voltage loss is relationship to power consumption. Therefore, when Vdd=−25 V, if Vin=0, Vout=about −25 V, and if Vin=−25 V, Vout=about 0. From FIG. 6, it can be ascertained that the voltage loss of the inverter (organic thin film transistor) of Example 1, which was manufactured using a local etching process, is lower than that of each of the inverters of Comparative Example 1 and Comparative Example 2. In the inverter of Example 1, when Vin=0 or −25 V, voltage loss is about 2˜3V, but, in the inverter of Comparative Example 1 and Comparative Example 2, when Vin=0 or −25 V, voltage loss is about 5˜10V. Meanwhile, in an electronic circuit, the term “gain value” is referred to as an ability to improve the signals or the like input through a circuit. In the case of the inverter of Example 1 manufactured using a local etching process, when Vdd=−25V, the gain value thereof is about 35, which is higher than that (15) of the inverter of Comparative Example 1 and that (30) of the inverter of Comparative Example 2.

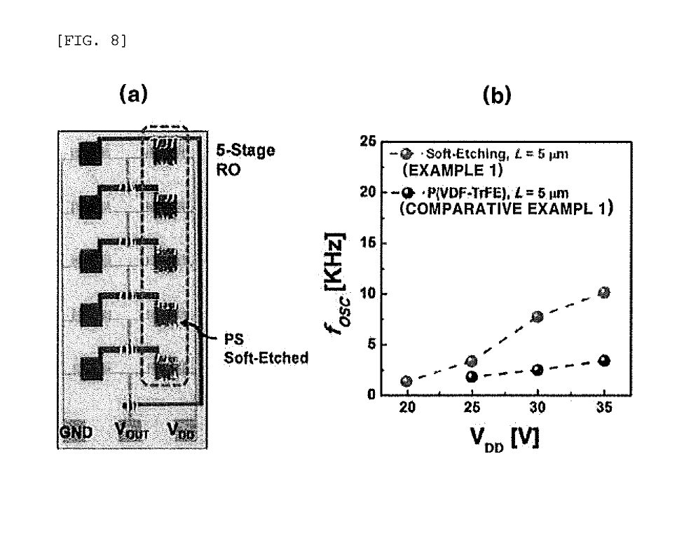

FIG. 8 presents a photograph (a) of a ring oscillator manufactured using the organic thin film transistor of Example 1 and a graph (b) showing the characteristics of the ring oscillator, wherein Fosc characteristics of the organic thin film transistors of Example 1 and Comparative Example 1 are shown.

Theoretically, oscillation frequency (Fosc) increases in inverse proportion to the square of length (L) of a channel of the transistor used. In the case of the inverter of Example 1 manufactured by an etching process using inkjet printing, higher oscillation frequency (Fosc) can obtained, compared to in the case of the inverter of Comparative Example 1 manufactured using only P(VDF-TrFE). That is, in the case of the inverter of Example 1, the first insulation layer optimized by an etching process was used, and thus high charge mobility could be obtained from an N-type transistor and a P-type transistor. The oscillation frequency (Fosc) increases in proportion to the increase in charge mobility. From this fact, it can be ascertained that the inverter (Example 1) manufactured by the etching of a first insulation layer exhibits high oscillation frequency.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of manufacturing an organic thin film transistor, comprising the steps of:
forming a first insulation layer on a semiconductor layer;
locally etching the first insulation layer; and
forming a second insulation layer on the first insulation layer including the etched region thereof,
wherein the etching of the first insulation layer is conducted by inkjet printing.

2. A method of manufacturing an organic thin film transistor, comprising the steps of:
providing a substrate;
forming source/drain electrodes on the substrate;
forming an organic semiconductor layer on the source/drain electrodes;
forming a first insulation layer on the organic semiconductor layer;
locally etching a part of the first insulation layer;
forming a second insulation layer on the first insulation layer including the etched region thereof; and
forming a gate electrode on the second insulation layer,
wherein the first insulation layer is etched using an etching solvent by inkjet printing.

3. The method of claim 1 or 2, wherein the organic semiconductor layer includes both an N-type semiconductor layer and a P-type semiconductor layer, and the first insulation layer is different from the second insulation layer.

4. The method of claim 3, wherein, after the step of etching the first insulation layer, the first insulation layer or second insulation layer is applied onto the N-type semiconductor layer, and the first insulation layer or second insulation layer being in contact with the N-type semiconductor layer is made of any one of polystyrene (PS), a fluoropolymer (CYTOP), and poly(methylmethacrylate) (PMMA).

5. The method of claim 3, wherein, after the step of etching the first insulation layer, the first insulation layer or second insulation layer is applied onto the P-type semiconductor layer, and the first insulation layer or second insulation layer being in contact with the P-type semiconductor layer is made of any one of P(VDF-TrFE) (poly(vinylidene fluoride-trifluoroethylene)), (P(VDF-TrFE-CFE)) (poly(vinylidene fluoride-trifluoroethylene-1, 1-chlorofluoroethylene)), and P(VDF-TrFE-CTFE) (poly(vinylidene fluoride-trifluoroethylene-chlorotrifluoro ethylene)).

6. The method of claim 1, wherein, in the step of etching the first insulation layer, a part of the first insulation layer is locally etched using an etching solvent by inkjet printing, and the etching solvent is any one of: n-butyl acetate (n-BA), 2-ethoxyethanol (2-E), 3-methoxypropiontrile (3-M), propylene glycol methyl ether acetate (PGMEA), 1,2-dichloroethane (1,2-DCE), and 1-butanol (1-BuOH).

7. The method of claim 1, wherein the organic semiconductor is an amphoteric organic semiconductor, an N-type organic semiconductor or a P-type organic semiconductor,
wherein the amphoteric organic semiconductor is any one selected from among P(NDI2OD-T2)(Naphthalene-bis(dicarboximide) bithiophene), F8BT, PFO, DPPT-TT(diketopyrrolo-pyrrole-bithiophene), and PTVPhI-Eh;
the N-type organic semiconductor is any one selected from among an acene material, a completely-fluorinated acene material, a partially-fluorinated acene material, a partially-fluorinated oligothiophene material, a fullerene material, a substituent-containing fullerene material, a completely-fluorinated phthalocyanine material, a partially-fluorinated phthalocyanine material, a perylene tetracarboxylic diimide material, a perylene tetracarboxylic dianhydride material, a naphthalene tetracarboxylic diimide material, and a naphthalene tetracarboxylic dianhydride material; and
the P-type organic semiconductor is any one selected from among acene, poly-thienylenevinylene, poly-3-hexylthiophene, α-hexathienylene, naphthalene, α-6-thiophene, α-4-thiophene, rubrene, polythiophene, polyparaphenylenevinylene, polyparaphenylene, polythiophenevinylene, a polythiophene-heterocyclicaromatic copolymer, and triarylamine.

8. An organic thin film transistor, comprising:
a substrate;
source/drain electrodes disposed on the substrate and spaced apart from each other;
an organic semiconductor layer formed on the source/drain electrodes and including an N-type semiconductor layer and a P-type semiconductor layer;
a first insulation layer disposed on the entire surface of the organic semiconductor layer;
a second insulation layer disposed on the entire surface of the first insulation layer; and
a gate electrode disposed on the second insulation layer,
wherein the first insulation layer is etched on the N-type semiconductor layer or the P-type semiconductor layer by inkjet printing.

9. The organic thin film transistor of claim 8, wherein the first insulation layer is different from the second insulation layer.

10. The organic thin film transistor of claim 8, wherein the first insulation layer or second insulation layer is applied onto the N-type semiconductor layer, and the first insulation layer or second insulation layer being in contact with the N-type semiconductor layer is made of any one of polystyrene (PS), a fluoropolymer (CYTOP) and poly(methylmethacrylate) (PMMA).

11. The organic thin film transistor of claim 8, wherein the first insulation layer or second insulation layer is applied onto the P-type semiconductor layer, and the first insulation layer or second insulation layer being in contact with the P-type semiconductor layer is made of any one of P(VDF-TrFE) (poly(vinylidene fluoride-trifluoroethylene)), (P(VDF-TrFE-CFE)) (poly(vinylidene fluoride-trifluoroethylene-1, 1-chlorofluoroethylene)), and P(VDF-TrFE-CTFE) (poly(vinylidene fluoride-trifluoroethylene-chlorotrifluoro ethylene)).

12. The organic thin film transistor of claim 8, wherein a part of the first insulation layer is locally etched using an etching solvent by inkjet printing, and the etching solvent is any one of n-butyl acetate (n-BA), 2-ethoxyethanol (2-E), 3-methoxypropiontrile (3-M), propylene glycol methyl ether acetate (PGMEA), 1,2-dichloroethane (1,2-DCE), and 1-butanol (1-BuOH).
